(19) United States
(12) Patent Application Publication
(10) Pub. No.: US 2010/0276393 A1
(43) Pub. Date: Nov. 4, 2010

(54) PLASMA PROCESSING APPARATUS AND METHOD

(75) Inventors: Sang-Ho Woo, Icheon-si (KR); Il-Kwang Yang, Yongin-si (KR)

Correspondence Address: LRK Patent Law Firm, 1952 Gallows Rd, Suite 200, Vienna, VA, 22182, US

(73) Assignee: EUGENE TECHNOLOGY CO., LTD., Yongin-si (KR)

(21) Appl. No.: 12/811,720

(22) PCT Filed: Jan. 15, 2009
(86) PCT No.: PCT/KR09/00224

§ 371 Date: Jul. 6, 2010

(30) Foreign Application Priority Data
Jan. 15, 2008 (KR) 10-2008-0004550

(51) Int. Cl. H01L 21/3065

(52) U.S. Cl. 216/68; 156/345.35

(57) ABSTRACT

A plasma processing apparatus includes a chamber to provide an inner area in which a process is performed upon an object, and a plasma source to generate an electric field in the inner area and thereby to generate plasma from a source gas supplied in the inner area, wherein the plasma source comprises a top source provided in the top of the chamber, and a side source encompassing the side of the chamber and allowing current to flow from the one side of the chamber to the other side thereof.

### TECHNICAL FIELD

The present invention relates to a plasma processing apparatus and method, and more particularly to a method for treating an object in a chamber with plasma.

### BACKGROUND ART

A semiconductor apparatus includes a variety of layers laminated on a silicon substrate, the layers being deposited on the substrate through a deposition process. Such a deposition process involves several important issues which are essential for evaluation of the deposited layers and selection of suitable deposition methods.

The first issue related to deposition is quality of deposited films. The quality includes composition, contamination levels, defect levels, and mechanical and electrical properties. The composition of films may be varied depending on deposition conditions which are important in obtaining a specific composition.

The second issue is a uniform thickness of the cross-section of a wafer. Particularly, the thickness of film deposited on a non-planar pattern with a step is quite important. Whether or not the thickness of a deposited film is uniform is determined by step coverage, defined as a value obtained by dividing a minimal thickness of film deposited on the step by a thickness of film deposited on the pattern.

The third issue related to deposition is a filling space. The filling space includes a gap filling wherein the space between metal lines is filled with an insulating film including an oxide film. The gap is provided so as to mechanically and electrically insulate the metal lines from one another.

Of these, uniformity is an important issue involved in the deposition process. A non-uniform film causes metal lines to have a high electrical resistance and increases the risk of mechanical damage.

### DISCLOSURE OF INVENTION

### Technical Problem

Therefore, the present invention has been made in view of the above problems, and it is an object of the present invention to provide a plasma processing apparatus and method to secure processing uniformity.

### Technical Solution

In accordance with an aspect of the present invention, the above and other objects can be accomplished by the provision of a plasma processing apparatus including: a chamber to provide an inner area in which a process is performed upon an object; and a plasma source to generate an electric field in the inner area to thereby generate plasma from a source gas supplied in the inner area, wherein the plasma source includes: a top source disposed to cover the top surface of the chamber; and a side source being disposed to cover the side surface of the chamber and allowing electric current to flow from the one side of the chamber to the other side thereof.

The top source may extend from the center of the top of the chamber toward the edge of the top of the chamber by a predetermined curvature.

The top source may include: a center source extending by a predetermined curvature from the center of the top surface of the chamber to the edge of the top surface of the chamber; and an edge source extending in a radius direction from the end of the center source toward the edge of the chamber.

The top source may include: a center source extending by a predetermined curvature from the center of the top surface of the chamber toward the edge of the top surface of the chamber; a circular source extending from the end of the center source and having a predetermined diameter and a circular shape; and an edge source extending in a radius direction from the end of the center source toward the edge of the chamber.

The top source may include: a first top source; a second top source having a shape substantially identical to the first top source and a predetermined angle difference with reference to the first top source; and a third top source having a shape substantially identical to the first and second top sources and a predetermined angle difference with reference to the second top source.

The side source may include: a downward source extending such that it inclines downward from the top of the chamber toward the bottom thereof and including the electric current flowing from the top of the chamber toward the bottom of the chamber; and an upward source extending such that it inclines upward from the bottom of the chamber toward the top thereof and including the electric current flowing from the bottom of the chamber to the top of the chamber.

The side source may include: an upper source extending from the one side of the chamber toward the other side thereof; a lower source extending from the one side of the chamber to the other side thereof, the lower source being arranged under the top source; a downward source extending from the top of the chamber toward the bottom thereof and being connected to one end of the upper source, the downward source allowing electric current to flow from the top of the chamber to the bottom thereof; and an upward source extending from the bottom of the chamber to the top thereof and being connected to one end of the lower source, the upward source allowing electric current to flow from the bottom of the chamber toward the top thereof.

The side source may include: a first side source; a second top source having a shape substantially identical to the first top source and a predetermined angle difference with reference to the first top source; and a third top source having a shape substantially identical to the first and second top sources and a predetermined angle difference with reference to the second top source.

The plasma source may be a coil.

The plasma processing apparatus may further include: an RF generator connected to the top source, the RF generator serving to supply the electric current having a radio frequency to the top source; and a matching device interposed between the RF generator and the top source.

The chamber may be provided with a support member in which the object is loaded, the chamber may include a processing chamber operated by the plasma and a generating chamber to generate plasma from the plasma source, and the plasma source may be fed on the top and side of the generating chamber.

In accordance with another aspect of the present invention, there is provided a method for treating plasma, including: supplying a electric current to a plasma source to generate plasma in a chamber and treating an object supplied in the chamber with the plasma, wherein the plasma source includes a top source supplied on the top of the chamber and a side source encompassing the side of the chamber.

The electric current may be supplied through the side source from the one side of the chamber toward the other side thereof, and the electric current may flow from the top of the chamber to the bottom thereof, and then flow from the bottom of the chamber to the top thereof.

### Advantageous Effects

The present invention provides a plasma processing apparatus and method to form a uniform density of plasma in a chamber. Furthermore, in accordance with the present invention, processing uniformity for an object using plasma can be secured.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a schematic view illustrating a plasma processing apparatus according to the present invention;

FIGS. 2 to 4 are views illustrating a top source of FIG. 1;

FIGS. 5 to 7 are views illustrating a side source of FIG. 1;

FIG. 8 is a view illustrating an interior of the plasma source of FIGS. 1; and

FIG. 9 is a view illustrating a connecter connected to the top source of FIG. 1.

### BEST MODE FOR CARRYING OUT THE INVENTION

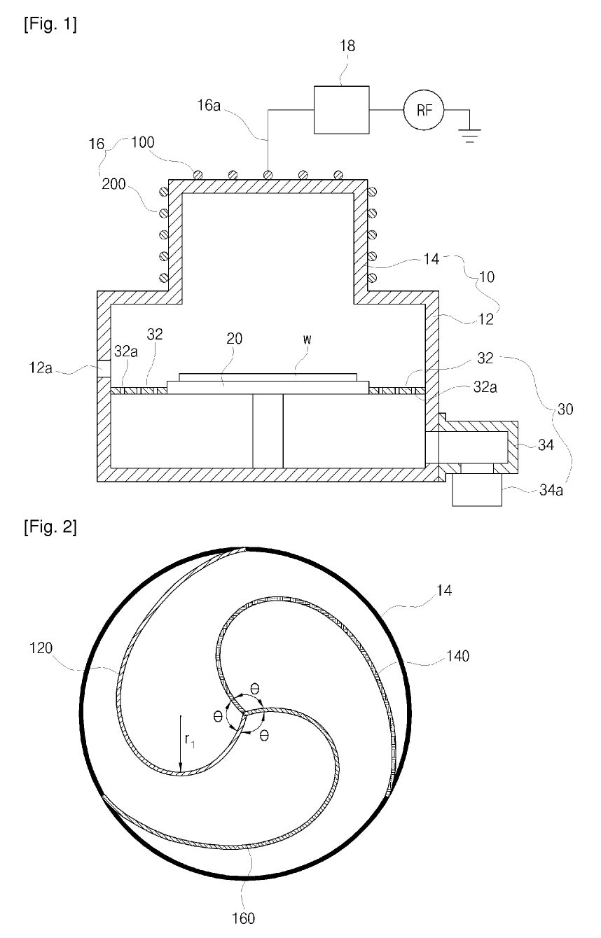

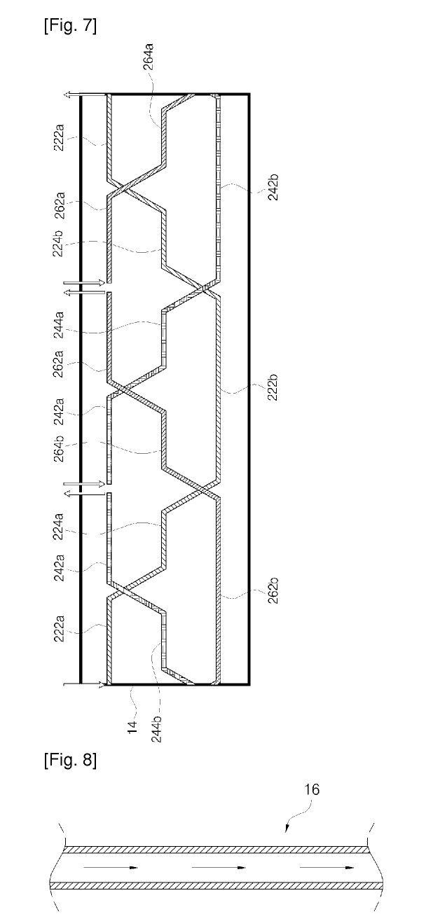

Hereinafter, exemplary embodiments of the present invention will be illustrated with reference to FIGS. 1 to 9 in more detail. Those skilled in the art will appreciate that various modifications, additions, and substitutions to the specific embodiments are possible, without departing from the scope and spirit of the invention. These embodiments are given for the purpose of illustration and are not to be construed as limiting the scope of the invention. Accordingly, in the drawings, the shapes of elements may be exaggerated for clearer description.

Meanwhile, an inductively coupled plasma (ICP) process will be illustrated as an example, but the present invention may be applied to a variety of plasma processes. Furthermore, a wafer will be described as an example of an object, but the present invention may be applied to a variety of objects.

FIG. 1 is a schematic view illustrating a plasma processing apparatus according to the present invention.

The plasma processing apparatus comprises a chamber 10 to provide an inner area where plasma processing is performed on a wafer (W). The chamber 10 is divided into a processing chamber 12 and a generating chamber 14, and the processing chamber 12 is an area where processing is performed on the wafer and the generating chamber 14 is an area where plasma is generated from a source gas supplied from the outside.

The processing chamber 12 is provided with a support plate 20 in which a wafer is loaded. The wafer W is introduced into the processing chamber 12 through an inlet 12a arranged at one side of the processing chamber 12 and the introduced wafer is placed on the support plate. In addition, the support plate 20 may be an electrostatic chuck (E-chuck) and may be provided with an additional back-side helium (He) cooling system (not shown) in order to precisely control the temperature of the wafer loaded on the support plate 20.

A plasma source 16 is disposed on the top surface and the outer circumference of the generating chamber 14. The plasma source 16 includes a top source 100 located on the top of the generating chamber 14 and a side source 200 located on the outer circumference thereof. The top source 100 is connected through an input line 16a to a radio frequency (RF) generator and a matching device 18 is provided between the top source 100 and the radio frequency generator. The side source 200 is connected to the top source 100. A radio frequency electric current supplied from the RF generator is introduced through the top source 100 into a bottom source 200. The top source 100 and the bottom source 200 convert the radio frequency electric current into a magnetic field, and generate plasma from the source gas supplied into the chamber 10.

The one side of the processing chamber 12 is connected to a discharge line 34 and a pump 34a is connected to the discharge line 34. Materials such as plasma and by-products generated in the chamber 10 are discharged from the chamber 10 through the discharge line 34, and the pump 34a forces the materials to be discharged outside. The plasma and by-products present in the chamber 10 are introduced through a discharge plate 32 into a discharge line 34. The discharge plate 32 is in contact with the support plate 20 such that it is substantially parallel to the support plate 20. The materials such as plasma and by-products present in the chamber 10 are introduced through discharge holes 32a formed in the discharge plate 32 into the discharge line 34.

FIGS. 2 to 4 are views illustrating the top source 100 of FIG. 1.

As shown in FIGS. 2 to 4, the top source 100 includes a first top source 120, a second top source 140 and a third top source 160. The first to third top sources 120, 140 and 160 are arranged such that they have substantially identical shapes and are at an identical angle. Accordingly, the first to third top sources 120, 140 and 160 are substantially identical to one another in angle difference.)(θ=60°).

FIG. 2 is a view illustrating the top source 100 according to one embodiment of the present invention. As shown in FIG. 2, the first top source 120 extends from the center of the top surface of the generating chamber 14 toward the edge of the top surface of the generating chamber 14 by a predetermined curvature (curvature diameter=r₁). Depending on the curvature diameter, a length of the first top source 120 may be varied, and the curvature diameter may be changed according to process conditions by an operator. The fore-mentioned input line 16a is connected to one end of the first to third top sources 120, 140 and 160 arranged on the center of the top surface of the generating chamber 14. Accordingly, the radio frequency electric current supplied to the top source 100 is transferred from the center of the top surface of the generating chamber 14 to the edge of the top surface of the generating chamber 14 in the form of a vortex rotating clockwise through the first to third top sources 120, 140 and 160.

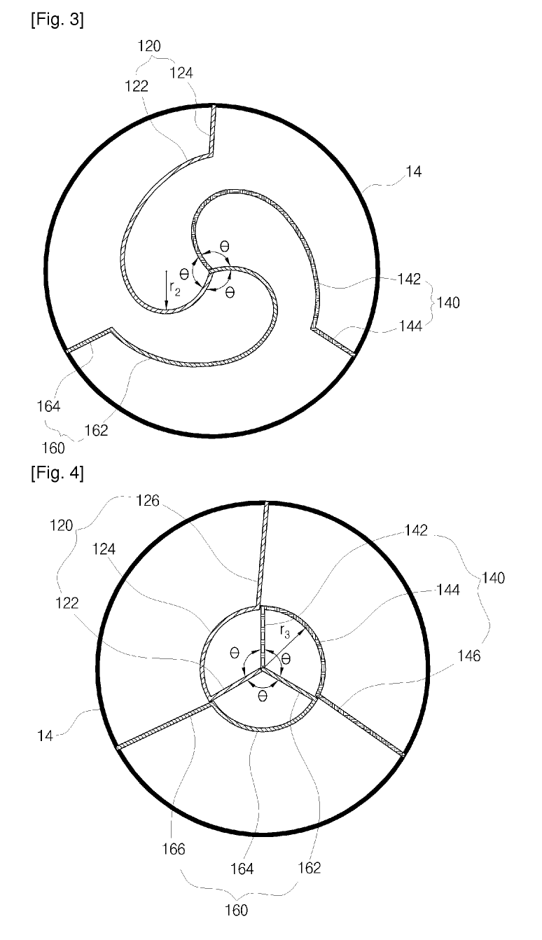

FIG. 3 is a view illustrating a top source 100 according to another embodiment of the present invention.

As shown in FIG. 3, a first top source 120 includes a first center source 122 and a first edge source 124. The first center source 122 extends from the center of the top surface of the generating chamber 14 to the edge of the top surface of the generating chamber 14 by a predetermined curvature (curvature diameter=r₂). The first edge source 124 extends diametrically from the end of the first center source 122 to the edge of the top surface of the generating chamber 14. Depending on the curvature diameter and the length of the first edge source 124, the length of the first top source 120 may be varied and the curvature diameter may be changed according to process conditions by an operator. The fore-mentioned input line 16a is connected to one end of the first to third top sources 120, 140 and 160 arranged on the top surface center of the generating chamber 14. Accordingly, the radio frequency electric current supplied to the top source 100 is transferred from the center of the top surface of the generating chamber 14 to the edge of the top surface of the generating chamber 14 in the form of a vortex rotating clockwise through first to third top sources 122, 142 and 162 and is then transferred in a radial direction from the first to third edge sources 124, 144 and 164 to the edge of the top surface of the generating chamber 14.

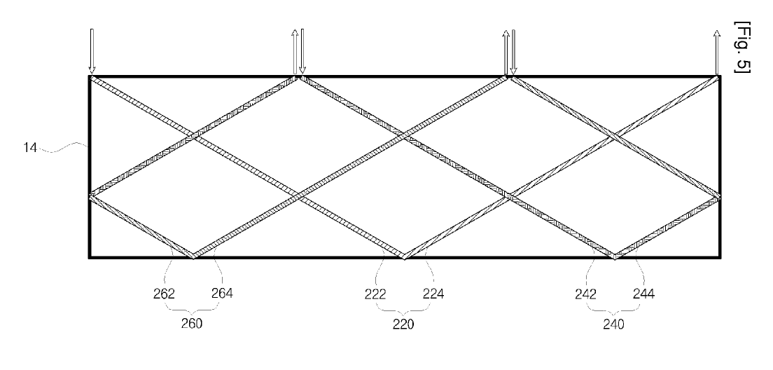

FIG. 4 is a view illustrating a top source 100 according to another embodiment of the present invention. As shown in FIG. 4, a first top source 120 includes a first center source 122, a first circular source 124 and a first edge source 126. The first center source 122 extends diametrically from the center of the top surface of the generating chamber 14 to the edge of the top surface of the generating chamber 14. The first circular source 124 extends from the one end of the first center source 122 and is in the form of a circle having a diameter r₃ corresponding to the length of the first center source 122. The first edge source 126 extends diametrically from the one end of the first circular source 124 to the edge of the top surface of the generating chamber 14. Meanwhile, depending on the length r₃ of the first center source 122, the length of the first center source 120 may be varied, and the curvature diameter may be changed according to process conditions by an operator. The fore-mentioned input line 16a is connected to one end of the first to third top sources 120, 140 and 160 arranged on the center of the top surface of the generating chamber 14. Accordingly, the radio frequency electric current supplied to the top source 100 is transferred from the center of the top surface of the generating chamber 14 to the edge of the top surface of the generating chamber 14, rotated by a predetermined angle θ through the first to third circular sources 124, 144 and 164 and then transferred in a radial direction through the first to third edge sources 126, 146 and 166 toward the edge of the top surface of the generating chamber 14.

The top source 100 generates plasma having a uniform density inside the generating chamber 14 in a radius direction of the top surface thereof. Since the side source 200 is located on the outer circumference of the generating chamber 14, the density of plasma generated by the side source 200 increases as the plasma becomes closer to the outer circumference of the generating chamber 14, and the density decreases as the plasma is farther from the outer circumference of the generating chamber 14. Since the top source 100 extends from the center of the top surface of the generating chamber 14 to the edge of the top surface of the generating chamber 14, the density of plasma generated by the top source 100 has a uniform density along a radius direction of the top surface of the generating chamber 14. Meanwhile, the first to third sources 120, 140 and 160 illustrated in FIGS. 2 to 4 are insulated from one another.

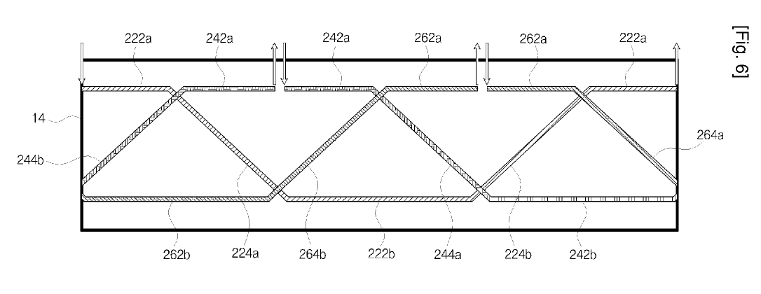

FIGS. 5 to 7 are views illustrating the side source 200 of FIG. 1. FIGS. 5 to 7 illustrate spread views of the outer circumference surface of the generating chamber 14 shown in FIG. 1, and the side source 200 shown in FIGS. 5 to 7 is arranged on the circumference surface of the generating chamber 14. As shown in FIGS. 5 to 7, the side source 200 includes the first side source 220, the second side source 240, and the third side source 260, and the first to third side sources 220, 240 and 260 have substantially identical angle differences)(θ=60°) and one ends thereof are connected to one end of the first to third top sources 120, 140 and 160, respectively. The first to third side sources 220, 240 and 260 have substantially identical shapes and radio frequency electric current flows therein from one side of the generating chamber 14 to the other side thereof. In the present embodiment, radio frequency electric current flows in the first to third side sources 220, 240 and 260 in the same direction, but the radio frequency electiric current may flow therein along different directions.

FIG. 5 is a view illustrating the top source 100 according to one embodiment of the present invention.

As shown in FIG. 5, a first side source 220 includes a first downward source 222 and a first upward source 224. The end of the first downward source 222 is connected to one end of the first top source 120, and the first downward source 222 extends such that it inclines downward from the top of the generating chamber 14 to the bottom thereof. The one end of the first upward source 224 is connected to one end of the first downward source 222 and the first upward source 224 extends such that inclines upward from the bottom of the generating chamber 14 to the top thereof. The first side source 220 shown in FIG. 5 includes one first downward source 222 and one first upward source 224. Alternatively, the first side source 220 may include a plurality of first downward sources 222 and a plurality of first upward sources 224 which are alternately arranged. As mentioned above, radio frequency electric current transferred through the first to third top sources 120, 140 and 160 from the center of the top surface of the generating chamber 14 to the edge of the top surface thereof are supplied to the first to third side sources 220, 240 and 260 connected to the first to third top sources 120, 140 and 160, respectively. Then, the radio frequency electric current flows through the first to third downward sources 222, 242 and 262 from the top of the generating chamber 14 to the bottom thereof, and then flows through the first to third upward sources 224, 244 and 264 from the bottom of the generating chamber 14 to the top thereof.

FIG. 6 is a view illustrating the top source 100 according to another embodiment of the present invention. As shown in FIG. 6, the first side source 220 includes a first upper source 222a, a first lower source 222b, a first downward source 224a and a first upward source 224b. The one end of the first upper source 222a is connected to one end of the first top source 120 and the first upper source 222a extends from one side of the generating chamber 14 to the other side thereof such that it substantially parallels the top surface of the generating chamber 14. The first lower source 222b extends from one side of the generating chamber 14 to the other side such that it substantially parallels the first upper source 222a. The first upper source 222a and the first lower source 222b are connected to each other through the first downward source 224a which inclines downward from the first upper source 222a and through the first upward source 224b which inclines upward from the first lower source 222b. Unlike the first side source 220 shown in FIG. 5, the first side source 220 may include alternately arranged first upper sources 222a, first lower sources 222b, first downward sources 224a and first upward sources 224b.

As mentioned above, radio frequency electric current transferred through the first to third top sources 120, 140 and 160 from the center of the top surface of the generating chamber 14 to the edge of the top surface of the generating chamber 14 are supplied to the first to third side sources 220, 240 and 260 connected to the first to third top sources 120, 140 and 160, respectively. Next, the radio frequency electric current flows through the first to third upper sources 222a, 242a and 262a from the one side of the generating chamber 14 to the other side thereof, and then flows through the first to third downward sources 224a, 244a and 264a from the top of the generating chamber 14 to the bottom thereof. Next, the radio frequency electric current flows through the first to third lower sources 222b, 242b and 262b from the one side of the generating chamber 14 to the other side thereof and then flows through the first to third upward sources 224b, 244b and 264b from the bottom of the generating chamber 14 to the top thereof.

The afore-mentioned side source 100 generates plasma having a uniform density for the top and bottom directions of the generating chamber 14 in the generating chamber 14. Since the radio frequency electric current flowing along the side source 100 alternately flows in the top of the generating chamber 14 and the bottom thereof along the circumference surface thereof, a magnetic field generated by the radio frequency current is uniform in density for the top and bottom directions of the generating chamber 14, and the plasma generated by the magnetic field is also uniform in density for the top and bottom directions thereof. Meanwhile, the first to third side sources 220, 240 and 260 shown in FIGS. 5 to 7 are insulated from one another.

FIG. 8 is a view illustrating an inside of the plasma source 16 of FIG. 1. Radio frequency current flows in the plasma source 16 and the temperature of the plasma source 16 may thus be increased. Accordingly, a refrigerant may be introduced into the plasma source 16 in order to control the temperature of the plasma source 16, and the refrigerant may be adjusted to a predetermined temperature using a chiller (not shown).

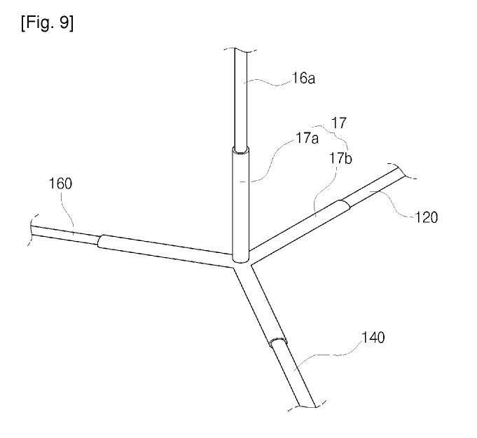

FIG. 9 is a view illustrating a connecter 17 connected to the top source 100 of FIG. 1. The connecter 17 includes an upper connecter 17a and a plurality of lower connecters 17b. The upper connecter 17a is connected to an input line 16a, and the lower connecters 17b are connected to first to third top sources 120, 140 and 160.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A plasma processing apparatus comprising:
a chamber to provide an inner area in which a process is performed upon an object; and
a plasma source to generate an electric field in the inner area and thereby to generate plasma from a source gas supplied in the inner area,
wherein the plasma source comprises:
a top source disposed to cover the top surface of the chamber; and
a side source being disposed to cover the side surface of the chamber and allowing electric current to flow from the one side of the chamber to the other side thereof.

2. The plasma processing apparatus according to claim 1, wherein the top source extends by a predetermined curvature from the center of the top of the chamber toward the edge of the top of the chamber.

3. The plasma processing apparatus according to claim 1, wherein the top source comprises:
a center source extending by a predetermined curvature from the center of the top surface of the chamber to the edge of the top surface of the chamber; and
an edge source extending in a radius direction from the end of the center source toward the edge of the chamber.

4. The plasma processing apparatus according to claim 1, wherein the top source comprises:
a center source extending by a predetermined curvature from the center of the top surface of the chamber toward the edge of the top surface of the chamber;
a circular source extending from the end of the center source and having a predetermined diameter and a circular shape; and
an edge source extending in a radius direction from the end of the center source toward the edge of the chamber.

5. The plasma processing apparatus according to claim 1, wherein the top source comprises:
a first top source;
a second top source having a shape substantially identical to the first top source and a predetermined angle difference with reference to the first top source; and
a third top source having a shape substantially identical to the first and second top sources and a predetermined angle difference with reference to the second top source.

6. The plasma processing apparatus according to claim 1, wherein the side source comprises:
a downward source extending such that it inclines downward from the top of the chamber toward the bottom thereof and allowing current to flow from the top of the chamber toward the bottom of the chamber; and
an upward source extending such that it inclines upward from the bottom of the chamber toward the top thereof and including the current flowing from the bottom of the chamber to the top of the chamber.

7. The plasma processing apparatus according to claim 1, wherein the side source comprises:
an upper source extending from the one side of the chamber toward the other side thereof;
a lower source extending from the one side of the chamber to the other side thereof, the lower source being arranged under the top source;
a downward source extending from the top of the chamber toward the bottom thereof and being connected to one end of the upper source, the downward source allowing current to flow from the top of the chamber to the bottom thereof; and
an upward source extending from the bottom of the chamber to the top thereof and being connected to one end of the lower source, the upward source allowing current to flow from the bottom of the chamber toward the top thereof.

8. The plasma processing apparatus according to claim 6, wherein the side source comprises:
a first side source;
a second top source having a shape substantially identical to the first top source and a predetermined angle difference with reference to the first top source; and
a third top source having a shape substantially identical to the first and second top sources and a predetermined angle difference with reference to the second top source.

9. The plasma processing apparatus according to claim 1, wherein the plasma source is a coil.

10. The plasma processing apparatus according to claim 1, further comprising:
a RE generator connected to the top source, the RF generator serving to supply the current having a radio frequency to the top source; and
a matching device interposed between the RF generator and the top source.

11 The plasma processing apparatus according to claim 1,
wherein the chamber is provided with a support member in which the object is loaded,
the chamber comprises a processing chamber operated by the plasma and a generating chamber to generate plasma from the plasma source, and
the plasma source is fed on the top and side of the generating chamber.

12. A method for treating plasma, comprising:
supplying a current to a plasma source to generate plasma in a chamber and treating an object supplied in the chamber with the plasma,
wherein the plasma source comprises a top source supplied on the top of the chamber and a side source encompassing the side of the chamber.

13. The method according to claim 12, wherein the current is supplied through the side source from the one side of the chamber toward the other side thereof, and the current flows from the top of the chamber to the bottom thereof and then flows from the bottom of the chamber to the top thereof.

14. The plasma processing apparatus according to claim 2, wherein the top source comprises:
a first top source;
a second top source having a shape substantially identical to the first top source and a predetermined angle difference with reference to the first top source; and
a third top source having a shape substantially identical to the first and second top sources and a predetermined angle difference with reference to the second top source.

15. The plasma processing apparatus according to claim 3, wherein the top source comprises:
a first top source;
a second top source having a shape substantially identical to the first top source and a predetermined angle difference with reference to the first top source; and
a third top source having a shape substantially identical to the first and second top sources and a predetermined angle difference with reference to the second top source.

16. The plasma processing apparatus according to claim 4, wherein the top source comprises:
a first top source;
a second top source having a shape substantially identical to the first top source and a predetermined angle difference with reference to the first top source; and
a third top source having a shape substantially identical to the first and second top sources and a predetermined angle difference with reference to the second top source.

17. The plasma processing apparatus according to claim 7, wherein the side source comprises:
a first side source;
a second top source having a shape substantially identical to the first top source and a predetermined angle difference with reference to the first top source; and
a third top source having a shape substantially identical to the first and second top sources and a predetermined angle difference with reference to the second top source.
